(19) United States
(12) Patent Application Publication
(10) Pub. No.: US 2026/0110716 A1
(43) Pub. Date: Apr. 23, 2026

(54) ELECTRICITY METER WITH GRID-SIDE VOLTAGE SENSING

(71) Applicant: Landis+Gyr Technology, Inc., Alpharetta, GA (US)

(72) Inventors: Doug BUSEKRUS, Alpharetta, GA (US); Matthew Eric KRAUS, Alpharetta, GA (US)

(21) Appl. No.: 19/116,212

(22) PCT Filed: Oct. 5, 2023
(86) PCT No.: PCT/US2023/076038

§ 371 Date: Mar. 27, 2025

(30) Foreign Application Priority Data
Oct. 6, 2022 (GB) 2214709.4
Apr. 19, 2023 (GB) 2305776.3

(51) Int. Cl. G01R 22/06; G01R 15/04; G01R 15/18

(52) U.S. Cl. CPC G01R 22/061; G01R 15/04; G01R 15/18

(57) ABSTRACT

An electricity meter (400) is disclosed. The electricity meter (400) comprises a power supply (460) for supplying power to measurement circuitry (430), and a surge protection device (455) for protecting an input (VA_LINE, VC_LINE) to the power supply. The measurement circuitry is configured to measure a voltage across the surge protection device. A corresponding method of operating an electricity meter is also disclosed, the method comprising configuring measurement circuitry to measure a voltage across a surge protection device, wherein the surge protection device is configured to protect an input to a power supply configured to supply power to the measurement circuitry.

### TECHNICAL FIELD OF THE DISCLOSURE

The present disclosure is in the field of electricity meters for metering of electricity consumption, such as in residential and commercial premises. The disclosure relates, in particular, to electricity meters having grid-side voltage sensing functionality.

### BACKGROUND

An electricity meter, also known in the art as an electrical power meter, electric meter or electrical meter, is a device that measures an amount of electrical power consumed by one or more electrically powered devices over a time interval, such as at a residential or commercial premises.

Electricity meters are typically installed at premises for purposes of billing and monitoring of consumption. In some examples, electricity meters may be manually, periodically read to determine a level of electrical power consumption. In other examples, advanced electricity meters known in the art as ‘smart meters’ may be configured to communicate with a utility provider, e.g. wirelessly, to provide electrical power consumption information and/or receive billing information and/or control signals.

Electricity, e.g. electrical power, may be delivered to a premises by a range of available service types, such as: single phase three wire commonly used in residential premises the United States; three phase four wire Wye commonly used in commercial premises in the United States; and three phase three wire delta commonly used in industrial facilities in the Unites States. Different service types have associated electricity meter forms, e.g. 2S, 3S, 5S, etc., as is well known in the art, and as described below in further detail.

Electricity meters must be designed to be safe and robust. For example, electricity meters must be capable of withstanding substantial electrical surges. In an example, a lightning strike may induce a substantial voltage spike and/or current surge at an input to an electricity meter. In another example, short circuiting of one or more loads coupled to an electricity meter may induce a substantial voltage spike and/or current surge.

Furthermore, in use, electricity meters must be capable of monitoring both ‘load-side’ and ‘grid-side’ voltages. In particular, electricity meters implementing service disconnect switches between a load-side and a grid-side of the electricity meter, for selectively disconnecting a power supply at the grid-side from a load at the load-side, may require accurate measurements of both load-side and grid-side voltages prior to reconnection of the power supply.

The load-side of an electricity meter may refer to a connection of the electricity meter to an electrical power consuming load. The grid-side of an electricity meter may refer to a connection of the electricity meter to a power supply line from a utility provider, e.g. from the electrical grid.

In order to ensure sufficient reliability of electricity meters, expensive components and considerable Printed Circuit Board (PCB) spacing may be needed to tolerate large voltage surges on both the load-side and the grid-side voltage connections, wherein both load-side and the grid-side voltages may be measured by the electricity meter. Such features may substantially contribute to manufacturing costs of electricity meters.

It is therefore desirable to provide an electricity meter that is relatively low-cost to manufacture, yet capable of tolerating large voltage surges on both a load-side and a grid-side voltage, while also enabling effective metrology of electrical power consumption and safe control of service disconnection functionality.

It is therefore an aim of at least one embodiment of at least one aspect of the present disclosure to obviate or at least mitigate at least one of the above identified shortcomings of the prior art.

### SUMMARY

The present disclosure is in the field of electricity meters for metering of electricity consumption, such as in residential and commercial premises. The disclosure relates, in particular, to electricity meters having grid-side voltage sensing functionality.

According to a first aspect of the disclosure, there is provided an electricity meter comprising: a power supply for supplying power to measurement circuitry; and a surge protection device for protecting an input to the power supply. The measurement circuitry is configured to measure a voltage across the surge protection device.

Advantageously, by implementing a measurement of the voltage across the surge protection device, expensive resistor strings that would typically be dedicated to the grid side voltage measurement in prior art electricity meters would be eliminated, thereby reducing overall manufacturing costs.

Instead, lower cost resistors may be placed across the surge protection device on the power supply, enabling an alternative means to measure the grid-side voltage.

In such an electricity meter, voltage measurements for purposes of metrology of electrical power consumption may alternatively come from a load-side resistor string, that may otherwise only be used for detection of customer power generation.

Furthermore, advantageously such a configuration enables the electricity meter to maintain a reference to grid-side voltages even when a service disconnect switch is configured to disconnect the load-side from the grid-side. This may be particularly important for detection of co-generation scenarios, such as when a user has implemented power generation capabilities, because reconnection of the load-side to grid-side while co-generation is underway may result in catastrophic damage to the electricity meter and/or may be dangerous.

By removing expensive resistor strings on the grid-side, an overall number of components in high voltage areas of a PCB within the electricity meter may be reduced. Furthermore, board slots that may be required between the voltage strings for purposes of electrical isolation may also be eliminated.

Such an overall reduction on PCB space may help reduce an overall cost of the PCBs, by more efficient penalization of the PCBs during manufacture.

The surge protection device may comprise at least one of: a Metal-Oxide Varistor (MOV); a Gas Discharge Tube (GDT); a Transient Voltage Suppressor (TVS) diode; and/or a Polymeric Positive Temperature Coefficient Device (PPTC).

The input may comprise a first voltage input and a second voltage input. The surge protection device may be connected to a first node coupled to the first voltage input and a second node coupled to the second voltage input.

In some examples, a plurality of surge protection devices may be implemented, For example, in other embodiments falling within the scope of the disclosure, more than two voltage inputs may be implemented. In some examples, each voltage input may be protected by at least one surge protection device.

In use, the first voltage input may comprise a first phase and the second voltage input may comprise a second phase out of phase with the first phase.

For example, the second phase may be an anti-phase, e.g. 180 degrees out of phase with the first phase. That is, in some embodiments, the electricity meter may be configured for use with a single phase three wire service type.

As described above, in other embodiments, the more than two voltage inputs may be implemented. For example, in some embodiments, the electricity meter may be configured for use with a three phase four wire Wye service type, or a three phase three wire delta service type.

The electricity meter may comprising a first voltage divider coupled to the first node and a second voltage divider coupled to the second node. The measurement circuitry may be configured to measure voltages at each of the first and second dividers to determine the voltage across the surge protection device.

Implementation of a voltage divider may provide an accurate, reliable means to measure a voltage, wherein a resistance of the divider may be selected such that sufficient precision is provided without excessive loading of power supply lines.

The first and second voltage dividers may be configured to tolerate a clamping voltage of the surge protection device.

That is, advantageously the surge protection device may limit a magnitude of a surge across the inputs to the power supply. As such, the first and second voltage dividers only need to be capable of withstanding a magnitude of surge that may be allowed by the surge protection device rather than, for example, 10,000 volt protection or greater that may otherwise be required for protection against surges due to lightning strikes or the like.

Various embodiments of voltage dividers may be implemented. For example, at least one of the first and second voltage dividers may comprise: a resistive divider; a capacitive divider; or an inductive divider.

In some embodiments, the electricity meter may comprise a first linear transformer coupled to the first node and a second linear transformer coupled to the second node. The measurement circuitry may be configured to measure voltages at each of the first and second linear transformers to determine the voltage across the surge protection device.

That is, a linear transformer may provide an alternative to one or both voltage dividers, thereby providing the measurement circuitry an alternative means to determine the voltage across the surge protection device.

The electricity meter may further comprising a surge protection element between the first voltage input and the first node.

The surge protection element may be a resistor.

In some embodiments the measurement circuitry may comprise a processor configured to: obtain samples of the measured voltage across the surge protection device; detect when a time period of distortion of the measured voltage across the surge protection device begins; obtain current values at an input terminal of the power supply during the time period; use the current values to determine a voltage drop across the surge protection device during the time period; and modify samples of the measured voltage across the surge protection device obtained during the time period based on the voltage drop across the surge protection device during the time period.

The electricity meter may further comprise a current sensing device arranged to output said current values. Advantageously, accurate current values at the input terminal of the power supply during the time period can thereby be obtained. The current sensing device may be connected between the first node and the input terminal.

Alternatively, the current values may be pre-stored in a memory accessible by the processor, and the processor is configured to obtain the current values by retrieving the current values from the memory. Advantageously, this avoids the need to have a current sensing device and thus saves PCB space. The processor may be configured to retrieve the current values from the memory based on an operating mode of the electricity meter.

In some embodiments the measurement circuitry may comprise a processor configured to: obtain samples of the measured voltage across the surge protection device; detect when a time period of distortion of the measured voltage across the surge protection device begins; determine a voltage peak during the time period of distortion using: (i) the measured voltage across the surge protection device when the time period of distortion begins, and (ii) a time between a zero-crossing of the measured voltage across the surge protection device, and when the time period of distortion of the measured voltage across the surge protection device begins; and modify samples of the measured voltage across the surge protection device obtained during the time period based on the voltage peak.

The power supply may comprise at least one rectifier and/or regulator circuit configured to supply power to the measurement circuitry.

For example, the power supply may comprise a rectifier, such as a bridge rectifier, configured to provide a direct current output from an alternating current input at the input to the power supply.

The power supply may provide an alternating current or a rectified direct current or to one or more regulators. For example, the one or more regulators may be configured to provide a range of voltages suitable for operation of different components of the smart meter. As a non-limiting example, the power supply may be configured to provide a 24 volt direct current supply to an actuator for a service disconnect switch; a 5 volt direct current supply to a transceiver driver, and a relatively low-voltage 3.3 volt direct current supply to a microprocessor circuit, etc.

The electricity meter may comprise an actuatable switch for selectively coupling a grid-side input of the electricity meter to a load side output of the electricity meter.

Such an actuatable switch may be known in the art as a ‘service disconnect switch’. In embodiments, the service disconnect switch may be operated under remote control, such as by a utility provider, to connect or disconnect the load-side from the grid-side at a premises, as described in more detail below.

The measurement circuitry may be configured to measure a load-side voltage at the load-side output of the actuatable switch.

Measurement of the load-side voltage may enable detection of co-generation activities, such as by use of a generator or solar panels, prior to a reconnection of the load-side to the grid side by the service disconnect switch, thereby improving a safety level of operation of the electricity meter.

The measurement circuitry may be configured to measure a load-side current at the load-side output of the actuatable switch.

The voltage across the surge protection device may correspond to a voltage at a grid-side input of the actuatable switch.

A comparison of grid-side and load-side voltage may be made prior to a reconnection of the load-side to the grid side by the service disconnect switch, improving a safety level of operation of the electricity meter. Such a comparison may be made by processing circuitry within the electricity meter, or by one or more remote device, e.g. a networked device operated by a utility provider.

The electricity meter may comprise control circuitry.

The control circuitry may comprise one or more processors.

The measurement circuitry may comprise an analog front end, which may comprise analog-to-digital converters, anti-aliasing filters, and the like. The analog front end may be communicably coupled to the control circuitry. The analog front end may be configured to perform analog measurements of the load-side and/or grid-side voltage and/or current, and convert such measurements into digital signals for communication to the control circuitry.

The electricity meter may comprise communication circuitry. For example, the electricity meter may comprise a transceiver configured for communication with a remote device. In examples, the communication circuitry may be configured as a node in a mesh network comprising a plurality of electricity meters. In examples, the communication circuitry may be configured to transmit data to a utility provider, wherein such data may relate to consumption of electricity and/or voltage levels at a grid-side and/or load-side of the electricity meter. In examples, the communication circuitry may be configured to receive a signal or data for controlling operation of the service disconnect switch.

The control circuitry may be configured to selectively actuate the actuatable switch based, at least in part, on: the voltage at a grid-side input as measured by the measurement circuitry; the load-side voltage as measured by the measurement circuitry; and/or data received by the communication circuitry.

Advantageously, the control circuity, or a remote device in communication with the control circuitry, may be able to identify any co-generation activity prior to configuring the actuatable switch, e.g. the service disconnect switch, to reconnect a load-side to a grid-side of the electricity meter.

According to a second aspect of the disclosure, there is provided a method of operating an electricity meter. The method comprises configuring measurement circuitry to measure a voltage across a surge protection device, wherein the surge protection device is configured to protect an input to a power supply configured to supply power to the measurement circuitry.

The method may comprise selectively operating an actuatable switch of the electricity meter. The switch may be configured to selectively couple a grid-side input of the electricity meter to a load side output of the electricity meter.

Selective actuation of the actuatable switch may be based, at least in part, on: the voltage at a grid-side input as measured by the measurement circuitry; the load-side voltage as measured by the measurement circuitry; and/or data received by communication circuitry of the electricity meter.

The method may comprise identifying a co-generation scenario based on the load-side voltage and the voltage at a grid-side input while the actuatable switch is configured to decouple the grid-side input of the electricity meter from the load side output of the electricity meter.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE DRAWINGS

These and other aspects of the present disclosure will now be described, by way of example only, with reference to the accompanying drawings, wherein:

FIG. 1 depicts a block diagram of a prior art electricity meter in series with a load, the electricity meter having the 2S form;

FIG. 2 depicts a further example of a prior art electricity meter;

FIG. 3 depicts an example of a prior art circuit from an electricity meter;

FIG. 4 depicts an electricity meter wherein measurement circuitry is configured to measure a voltage across a surge protection device, according to an embodiment of the disclosure;

FIG. 5 depicts an example of a circuit from an electricity meter, according to an embodiment of the disclosure;

FIG. 6 depicts an alternative example of a circuit from an electricity meter, according to a further embodiment of the disclosure;

FIG. 7 illustrates a distorted grid-side voltage waveform measured in the circuit of FIG. 5;

FIG. 8 illustrates a grid-side voltage waveform occurring on the grid;

FIG. 9 depicts a schematic block diagram of analog front end circuitry which may be used in the measurement circuitry of FIG. 4;

FIG. 10a is a flowchart illustrating a method which may be performed by a processor of the analog front end circuitry when the processor has knowledge of the current at an input terminal of a power supply of the circuit of FIG. 5;

FIG. 10b illustrates an example current waveform at an input terminal of a power supply of the circuit of FIG. 5;

FIG. 11 is a flowchart illustrating a method which may be performed by the processor of the analog front end circuitry when the processor has no knowledge of the current at the input terminal of a power supply of the circuit of FIG. 5;

FIG. 12 is a flowchart illustrating a method which may be performed by the processor of the analog front end circuitry to detect a time when distortion from clipping begins; and

FIG. 13 illustrates a distorted grid-side voltage waveform measured in the circuit of FIG. 5, and a second order derivative waveform computed from the distorted grid-side voltage waveform.

### DETAILED DESCRIPTION OF THE DRAWINGS

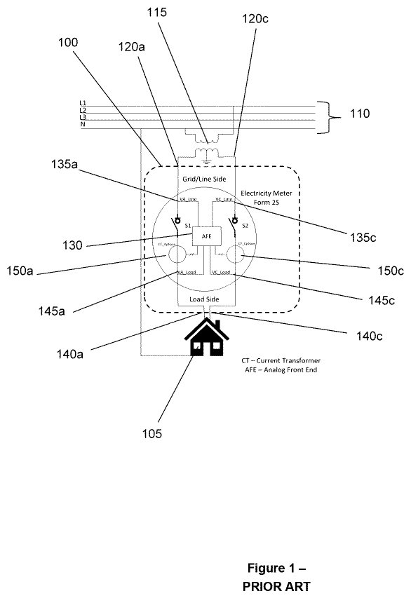

FIG. 1 depicts a block diagram of a prior art electricity meter 100. For purposes of example, the prior art electricity meter 100 is configured as a Form 2S service type electricity meter, which is a meter configured for use with a single phase, three wire service.

The prior art electricity meter 100 is installed in series with a load 105, which for purposes of exemplifying a residential load is depicted as a house.

In use, a high-voltage power supply line 110 may provide a supply of electrical power from the grid, i.e. from a utility company. A transformer 115 may step down a voltage on the power supply line 110 to a voltage suitable for use by the load 105, e.g. 240 volts or 110 volts, or the like.

In the example electricity meter 100, a first input terminal 120a is connected to a supply voltage from the transformer 115 having a first phase and a second input terminal 120c is connected to a supply voltage from the transformer 115 having a second phase. The second phase is out of phase with the first phase. For example, the second phase may be an anti-phase, e.g. 180 degrees out of phase with the first phase. The first input terminal 120a may be known in the art as a “Phase A” input. The second input terminal 120c may be known in the art as a “Phase C”input.

A first output terminal 140a and a second output terminal 140c are connected to the load 105, and therefore can provide electrical power to the load 105.

The example electricity meter 100 comprises a first actuatable switch S1 and a second actuatable switch S2. The first actuatable switch S1 may selectively disconnect/connect the grid-side first input terminal 120a from the load-side first output terminal 140a. The second actuatable switch S2 may selectively disconnect/connect the grid-side second input terminal 120c from the load-side second output terminal 140c.

In use, the first actuatable switch S1 and the second actuatable switch S2 may be collectively known as a ‘service disconnect switch’, and may be configured to selectively connect/disconnect the load-side from the grid-side of the electricity meter 100. That is, the first actuatable switch S1 may selectively couple the first input terminal 120a to the first output terminal 140a and the second actuatable switch S2 may selectively couple the second input terminal 120c to the second output terminal 140c.

The example electricity meter 100 comprises measurement circuitry 130. The measurement circuitry 130 comprises an Analog Front End, denoted ‘AFE’ in FIG. 1. The measurement circuitry 130, and in particular the AFE, may comprise analog-to-digital converters, anti-aliasing filters, and the like. The analog front end may be communicably coupled to control circuitry and/or processing circuitry (not shown). The analog front end may be configured to perform analog measurements of the grid-side voltage and/or load-side voltage and/or current, and convert such measurements into digital signals for communication to the control circuitry, as described further below.

A ‘Phase A’ input voltage level at the first input terminal 120a, e.g. at the grid-side of the first actuatable switch S1, may be measured by the measurement circuitry 130, such as by sensing a voltage at a string of resistors (not shown) at a first node 135a coupled to the first input terminal 120a.

A ‘Phase C’ input voltage level at the second input terminal 120c, e.g. at the grid-side of the second actuatable switch S2, may be measured by the measurement circuitry 130, such as by sensing a voltage at a string of resistors (not shown) at a second node 135c coupled to the second input terminal 120c.

A ‘Phase A’ output voltage level at the first output terminal 140a, e.g. at the load-side of the first actuatable switch S1, may be measured by the measurement circuitry 130, such as by sensing a voltage at a string of resistors (not shown) at a third node 145a coupled to the first output terminal 140a.

A ‘Phase C’ output voltage level at the second output terminal 140c, e.g. at the load-side of the second actuatable switch S2, may be measured by the measurement circuitry 130, such as by sensing a voltage at a string of resistors (not shown) at a fourth node 145c coupled to the second output terminal 140c.

The electricity meter 100 also comprises a first current transformer 150a for providing a signal to the measurement circuitry 130 corresponding to a ‘Phase A’ current at the load-side of the first actuatable switch S1.

The electricity meter 100 also comprises a second current transformer 150c for providing a signal to the measurement circuitry 130 corresponding to a phase C current at the load-side of the second actuatable switch S2.

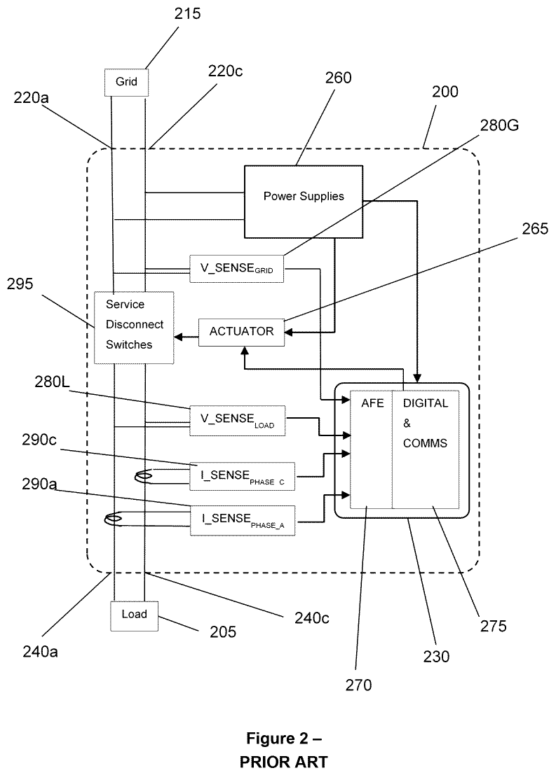

FIG. 2 depicts a more detailed example of a prior art electricity meter 200, generally corresponding to the Form 2S electricity meter 100 of FIG. 1, but showing in more detail specific components of the electricity meter 200.

The prior art electricity meter 200 is installed in series between a grid 215 and a load 205.

In the example electricity meter 200, a first input terminal 220a is connected to a supply voltage from the grid 215 having a first phase and a second input terminal 220c is connected to a supply voltage from the grid 215 having a second phase, wherein the second phase is out of phase with the first phase.

The first input terminal 220a and the second input terminal 220c may be provided at a service entrance of the electricity meter 200.

The first input terminal 220a may be known in the art as a “Phase A” input. The second input terminal 220c may be known in the art as a “Phase C” input.

A first output terminal 240a and a second output terminal 240c are connected to the load 205, and therefore can provide electrical power to the load 205.

The example electricity meter 200 comprises service disconnect switch 295, which may selectively disconnect/connect the grid 215 from the load 205.

The electricity meter 200 comprises an actuator 265 which may, for example, comprises a solenoid or the like for actuating the service disconnect switch 295.

The example electricity meter 200 comprises measurement circuitry 230. The measurement circuitry 230 comprises an analog front end 270. The measurement circuitry 230, and in particular the analog front end 270, may comprise analog-to-digital converters, anti-aliasing filters, and the like. In the example, the analog front end 270 is communicably coupled to digital circuitry 275. The analog front end 270 may be configured to perform analog measurements of the grid-side voltage and load-side voltage and current, and convert such measurements into digital signals for processing by the digital circuitry 275. In some examples, data corresponding to the processed measurements may be communicated to a remote device, such as another electricity meter in a mesh network, by the digital circuitry 275 which may comprise communications circuitry such as a transceiver.

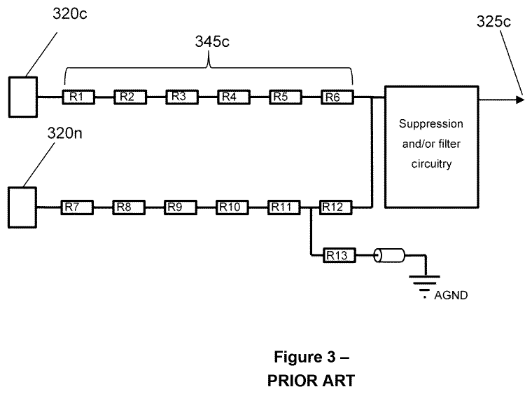

A grid voltage sensing circuit 280G, denoted V_SENSE_{GRID}, is configured for determining a voltage on each of the first and second input terminals 220a, 220c, thereby providing grid-side voltage measurements. The grid voltage sensing circuit 280G may be implemented using relatively expensive resistor strings (not shown), which are described in more detail below with reference to FIG. 3. Such expensive resistor strings may be capable of tolerating substantial voltage spikes and current surges, such as those that may be incurred due to a lighting strike. Such resistor strings may substantially contribute to an overall cost of manufacturing the electricity meter 200. The grid voltage sensing circuit 280G is coupled to the analog front end 270, enabling measurements of the grid-side voltage.

Similar to the electricity meter 100 of FIG. 1, the electricity meter 200 also comprises a load voltage sensing circuit 280L, denoted V_SENSE_{LOAD}, for sensing a voltage across the load 205, at a load-side of the service disconnect switch 295. The load voltage sensing circuit 280L is also coupled to the analog front end 270, enabling measurements of the load-side voltage. The load voltage sensing circuit 280L may also implement relatively expensive resistor strings.

A ‘Phase A’ electrical current flowing to the load 205 from the first input terminal 220a may be measured, for purposes of determining electrical power consumption by the load 205, using a first current sensing circuit 290a, denoted I_SENSE_{PHASE_A}. The first current sensing circuit 290a may comprise a current transformer. The first current sensing circuit 290a is coupled to the measurement circuitry 230, e.g. to one or more ADC channels of the analog front end 270.

A ‘Phase C’ electrical current flowing to the load 205 from the second input terminal 220c may be measured, for purposes of determining electrical power consumption by the load 205, using a second current sensing circuit 290c, denoted I_SENSE_{PHASE_A}. The second current sensing circuit 290c may comprise a current transformer. The second current sensing circuit 290c is coupled to the measurement circuitry 230, e.g. to one or more ADC channels of the analog front end 270.

The electricity meter 200 comprises a power supply 260. The power supply 260 receives power from the grid 215 via the first input terminal 220a and the second input terminal 220c. The power supply 260 provides power to components of the electricity meter 200. In the example, the power supply 260 provides electrical power to the actuator 265. The power supply 260 also provides electrical power to the measurement circuitry 230. In examples, the power supply 260 may comprise at least one rectifier and/or regulator circuit configured to supply power to the measurement circuitry 230 and the actuator 265. For example, the power supply 260 may comprise a rectifier, such as a bridge rectifier, configured to provide a direct current output from an alternating current input at the input to the power supply 260. The power supply 260 may comprise one or more regulators configured to provide a range of voltages suitable for operation of different components of the smart meter. As an example, the power supply 260 may be configured to provide a 24 volt direct current supply to the actuator 265, a 5 volt direct current supply to the analog front end 270, and a 3.3V direct current supply to a microprocessor circuit within the digital circuitry 275.

FIG. 3 depicts an example of a circuit 300 from a prior art electricity meter having the 2S form, such as the electricity meter 100, 200.

An input terminal 320c may correspond to the second input terminals 120c, 220c of FIGS. 1 and 2. Also depicted is a further input terminal 320n, which in use may be coupled to a neutral line.

An output 325c may be an input to measurement circuitry. For example, the output 325c may be an input to an anti-aliasing filter of an ADC for measuring a voltage at the input terminal 320c.

A resistor string 345c comprising resistors R1 to R6 is coupled to the input terminal 320c. In use, a voltage across resistor string R1 to R6 may be used to measure the voltage at the input terminals 320c, e.g. at a grid-side of a service disconnect switch 295 in the electricity meter 200. Such a resistors string 345c may be expensive to implement, and may consume substantial PCB space incurring costs and product form-factor limitations.

It will be understood that the circuit 300 of FIG. 3 is provided merely for purposes of example, and different meter forms may implement different resistor string configurations. For example, for a “single” phase form such as the 2S meter form, resistors R7 to R12 may be populated. For a “polyphase” meter form such as the 12S meter form, resistors R1 to R6 may be populated. Additionally, for the 12S meter form, resistors R7 to R11 may be populated with 0 ohm values, to tie the further input terminal 320n coupled to a neutral line to AGND. Thus, different meter forms may implement different configurations of relatively expensive resistor strings.

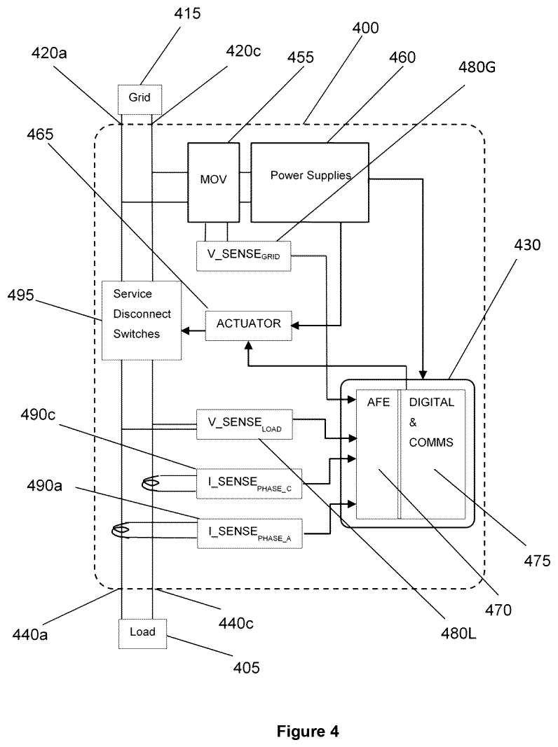

FIG. 4 depicts an electricity meter 400 according to an embodiment of the disclosure, wherein measurement circuitry 430 is configured to measure a voltage across a surge protection device 455 of the power supply 460.

The electricity meter 400 is installed in series between a grid 415 and a load 405. In the example electricity meter 400, a first input terminal 420a is connected to a supply voltage from the grid 415 having a first phase and a second input terminal 420c is connected to a supply voltage from the grid 415 having a second phase, wherein the second phase is out of phase with the first phase. The first input terminal 420a and the second input terminal 420c may be provided at a service entrance of the electricity meter 400.

The first input terminal 420a may be known in the art as a “Phase A” input. The second input terminal 420c may be known in the art as a “Phase C” input.

A first output terminal 440a and a second output terminal 440c are connected to the load 405, and therefore can provide electrical power to the load 405.

The example electricity meter 400 comprises service disconnect switch 495, which may selectively disconnect/connect the grid 415 from the load 405.

The electricity meter 400 comprises an actuator 465 which may, for example, comprises a solenoid for actuating the service disconnect switch 495.

The example electricity meter 400 comprises measurement circuitry 430. The measurement circuitry 430 comprises an analog front end 470. The measurement circuitry 430, and in particular the analog front end 470, may comprise analog-to-digital converters, anti-aliasing filters, and the like. In the example, the analog front end 470 is communicably coupled to digital circuitry 475. The analog front end 470 may be configured to perform analog measurements of the grid-side voltage and load-side voltage and current, and convert such measurements into digital signals for processing by the digital circuitry 475. In some examples, data corresponding to the processed measurements may be communicated to a remote device, such as another electricity meter in a mesh network, by the digital circuitry 475 which may comprises communications circuitry such as a transceiver.

Similar to the electricity meter 200 of FIG. 2, the electricity meter 400 comprises a load voltage sensing circuit 480L, denoted V_SENSE_{LOAD}, for sensing a voltage across the load 405, at a load-side of the service disconnect switch 495. The load voltage sensing circuit 480L is also coupled to the analog front end 470, enabling measurements of the load-side voltage. The load voltage sensing circuit 480L may also implement relatively expensive resistor strings.

A ‘Phase A’ electrical current flowing to the load 405 from the first input terminal 420a may be measured, for purposes of determining electrical power consumption by the load 205, using a first current sensing circuit 490a, denoted I_SENSE_{PHASE_A}. The first current sensing circuit 490a may comprise a current transformer. The first current sensing circuit 490a is coupled to the measurement circuitry 430, e.g. to one or more ADC channels of the analog front end 470.

A ‘Phase C’ electrical current flowing to the load 405 from the second input terminal 420c may be measured, for purposes of determining electrical power consumption by the load 405, using a second current sensing circuit 490c, denoted I_SENSE_{PHASE_A}. The second current sensing circuit 490c may comprise a current transformer. The second current sensing circuit 490c is coupled to the measurement circuitry 430, e.g. to one or more ADC channels of the analog front end 470.

The electricity meter 400 comprises a power supply 460. The power supply 460 receives power from the grid 415 via the first input terminal 420a and the second input terminal 420c. The power supply 460 provides power to components of the electricity meter 400. In the example, the power supply 460 provides electrical power to the actuator 465. The power supply 460 also provides electrical power to the measurement circuitry 430. In examples, the power supply 460 may comprise at least one rectifier and/or regulator circuit configured to supply power to the measurement circuitry 430 and the actuator 465. For example, the power supply 460 may comprise a rectifier, such as a bridge rectifier, configured to provide a direct current output from an alternating current input at the input to the power supply 460. The power supply 460 may comprise one or more regulators configured to provide a range of voltages suitable for operation of different components of the smart meter. As an example, the power supply 460 may be configured to provide a 24 volt direct current supply to the actuator 465, a 5 volt direct current supply to the analog front end 470, and a 3.3V direct current supply to a microprocessor circuit within the digital circuitry 475.

A surge protection device 455 is provided at an input to the power supply 460. The surge protection device 455 is configured to protect an input to the power supply from surges in voltage and/or current that may be induced by a lightning strike, a short circuit, or the like.

In a preferred embodiment, the surge protection device 455 may be implemented as a Metal-Oxide Varistor (MOV). In other embodiments, the surge protection device may comprise at least one of: a Gas Discharge Tube (GDT); a Transient Voltage Suppressor (TVS) diode; and/or a Polymeric Positive Temperature Coefficient Device (PPTC).

Although reference is made to a single surge protection device 455, it will be understood that in embodiment falling within the scope of the disclosure, a plurality of surge protection devices may be implemented.

The surge protection device 455 may limit a voltage seen at the input of the power supply.

A grid voltage sensing circuit 480G, denoted V_SENSE_{GRID}, is configured for determining a voltage across the surge protection device 455, thereby providing grid-side voltage measurements.

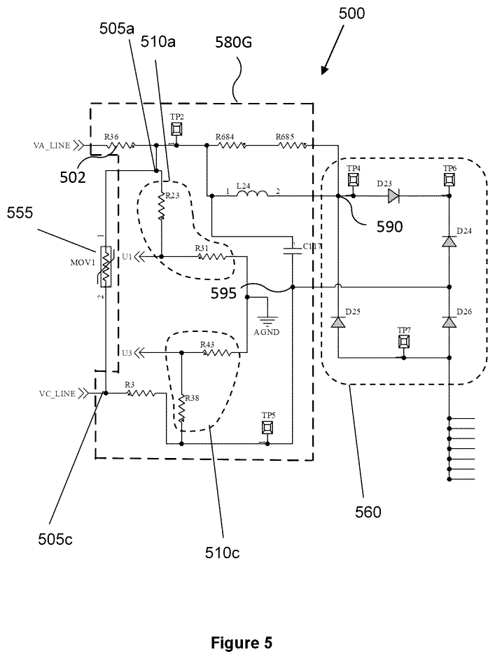

Unlike the grid voltage sensing circuit 280G of FIG. 2, in the embodiment of FIG. 4 the grid voltage sensing circuit 480G does not require expensive resistor strings, as described in more detail below with reference to FIG. 5.

The grid voltage sensing circuit 480G is coupled to the analog front end 470, enabling measurements of the grid-side voltage. By implementing a measurement of the grid-side voltage across the surge protection device 455, expensive resistor strings, e.g. resistor strings 345a and 345c depicted in FIG. 3, that would typically be dedicated to the grid side voltage measurement in prior art electricity meters 100, 200 would be eliminated, reducing overall manufacturing costs of the electricity meter 400.

That is, because the surge protection device 455 limits a voltage at the input of the power supply, the grid voltage sensing circuit 480G only needs to be capable of tolerating the maximum voltage allowed by the surge protection device 455.

In such an electricity meter 400, voltage measurements for purposes of metrology of electrical power consumption may come from a load-side resistor string, using the load voltage sensing circuit 480L that would otherwise only be used for detection of customer power generation.

In use, the measurement circuitry 430 may be configured to measure a voltage across the surge protection device 455 to provide an indication of a grid-side voltage

In use, operation of the service disconnect switch 495 to selectively couple a grid-side input of the electricity meter to a load side output of the electricity meter may be based on a grid-side voltage measured across the surge protection device 455.

That is, selective actuation of the service disconnect switch 495 may be based, at least in part, on: the voltage at a grid-side input as measured by the measurement circuitry 430; the load-side voltage as measured by the measurement circuitry 430; and/or data received by communication circuitry of the electricity meter 400.

In some examples, a co-generation scenario may be identified based on a comparison of the load-side voltage and the voltage at a grid-side input while the actuatable switch 495 is configured to decouple the grid-side input of the electricity meter 400 from the load side output of the electricity meter.

FIG. 5 depicts an example of a circuit 500 from an electricity meter, such as the electricity meter 400 of FIG. 4, according to an embodiment of the disclosure.

In the example circuit of FIG. 5, “VA_LINE” represents an input coupled to a first input terminal, e.g., the first input terminal 420a. “VC_LINE” represents an input coupled to a second input terminal, e.g., the second input terminal 420c.

A first output, denoted ‘U1’ may be an input to measurement circuitry, e.g. measurement circuitry 430. A second output, denoted ‘U3’ may be an input to measurement circuitry, e.g. measurement circuitry 430. In use, U1 and U3 may be inputs to ADC anti-aliasing filters of the measurement circuitry 430.

In the example circuit, a power supply 560 is implemented as a bridge rectifier. That is, the power supply 560 may be configured provide a dc supply to other features of the electricity meter. In an example, the power supply 560 may correspond to the power supply 460 of the electricity meter 400 of FIG. 4.

A surge protection device 555 is provided across an input of the power supply. In the example circuit 500, the surge protection device 555 is implemented as a varistor, e.g. a MOV. The surge protection device 555 may correspond to the surge protection device 455 of the electricity meter 400 of FIG. 4.

In the example circuit 500, a grid voltage sensing circuit 580G is provided. The grid voltage sensing circuit 580G may correspond to the grid voltage sensing circuit 480G of the electricity meter 400 of FIG. 4. The surge protection device 555 is coupled to a first node 505a and a second node 505c of the grid voltage sensing circuit 580G.

A first voltage divider 510a is coupled to the first node 505a and a second voltage divider 510c coupled to the second node 505c. The first output ‘U1’ is a divided voltage from the first voltage divider 510a. The second output ‘U3’ is a divided voltage from the second voltage divider 510c. As such, the measurement circuitry 430 having U1 and U3 as inputs may be configured to measure voltages at each of the first and second dividers 510a, 510c to determine a voltage across the surge protection device 555.

In the example circuit 500, a surge protection element in the form of a resistor R36 502 is included as an additional lightning surge resistor. As shown in FIG. 5, the resistor R36 502 is placed between the first voltage input (VA_LINE) and the first node (505a). The resistor R36 502 is placed in front of the surge protection device 555 in order to limit the current flowing into the surge protection device 555 when a surge event occurs. The resistor R36 502 may for example be between 47 and 100 Ohms. The resistor R36 502 may for example be rated between 2-5 Watts.

In the example circuit 500, resistor R3 is included as a balancing resistor to account for power supply current draw shifting the AGND point of the 2S meter.

Although the first voltage divider 510a and the second voltage divider of the circuit 500 of FIG. 5 are resistive dividers, it will be understood that in other embodiments other types of voltage dividers may be implemented. For example, in embodiments one or both of the first and second voltage dividers 510a, 510c may be implemented as a capacitive divider or an inductive divider. Furthermore, in yet further examples, one of both of the first and second voltage dividers 510a, 510c may be replaced with a linear transformer for determining the voltage across the surge protection device 555.

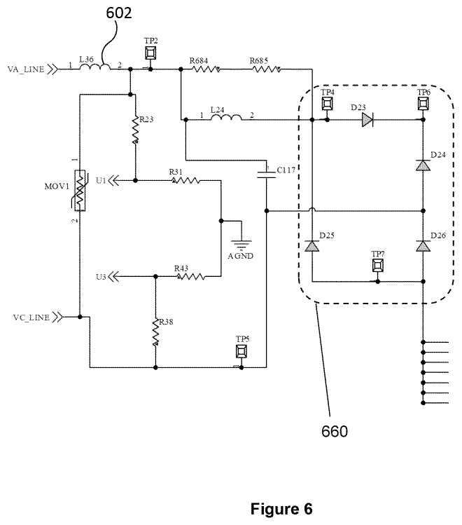

FIG. 6 depicts an example of an alternative circuit 600 for an electricity meter, such as the electricity meter 400 of FIG. 4, according to an embodiment of the disclosure.

Features of the circuit 600 generally correspond to those of circuit 500, and therefore are not described in more detail for purposes of brevity.

However, in comparison to the circuit 500 of FIG. 5, in the circuit 600 of FIG. 6 the resistor R36 502 is replaced with a surge protection element in the form of an inductor denoted ‘L36’ 602. Advantageously, an inductor L36 602 in place of resistor R36 502 could also be used to limit surge currents, and may reduce a distortion of a measured voltage due to any current draw of the power supply 660.

In this regard, the inventors have identified methods to compensate for the distortion of the measured voltage in the example circuit 500 in which a surge protection element is employed. These methods are particularly advantageous when the surge protection element is in the form of the surge resistor R36 502. As power is drawn into the power supply 560, a voltage drop will occur across the surge resistor R36 502 due to the peak of the grid-side voltage as it starts to conduct through the diodes of the power supply 560 and then recharges a bulk capacitor (not shown in the figures), this causes a distortion in the sensed grid-side voltage that is not an accurate reflection of the voltage on the grid. The bulk capacitor is not shown in the figures but may be placed between TP6 and TP7 in FIGS. 5 and 6.

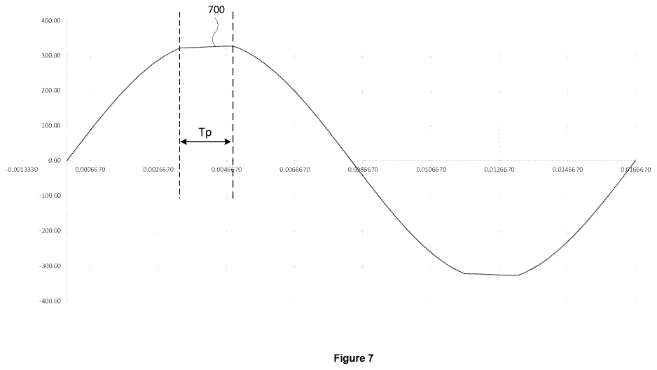

FIG. 7 illustrates a distorted grid-side voltage waveform 700 that may be measured by the grid voltage sensing circuit 580G of FIG. 5. As shown, the distorted grid-side voltage waveform 700 experiences a clipping effect during a time period Tp of distortion due to the power being drawn by the power supply 560.

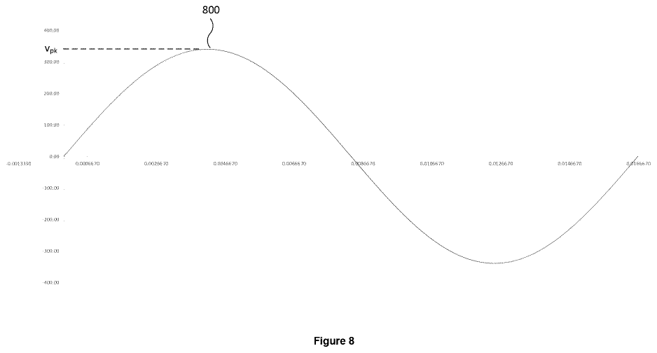

FIG. 8 illustrates a grid-side voltage waveform 800 occurring on the grid. In comparison with FIG. 8, it can be seen from the distorted grid-side voltage waveform 700 that a peak voltage Vₚₖ of the grid-side voltage is not accurately sensed by the grid voltage sensing circuit 580G due to the distortion introduced by the resistor R36 502

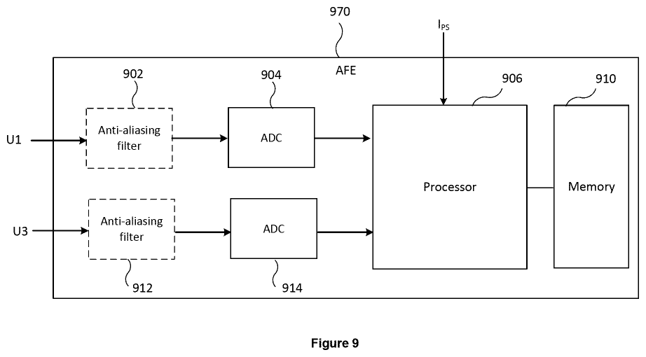

FIG. 9 depicts a schematic block diagram of analog front end circuitry 970 which may be used in the measurement circuitry of FIG. 4, to enable measurements of the grid-side voltage. The analog front end circuitry 970 may correspond to the analog front end circuitry 470 of the electricity meter 400 of FIG. 4.

As shown in FIG. 9, the first output ‘U1’ and second output ‘U3’ are processed before being supplied in digital form to a processor 906. The first output ‘U1’ and second output ‘U3’ may optionally be supplied as inputs to anti-aliasing filters 902,912 before being supplied to a respective analogue-to-digital converter (ADC) 904,914.

In accordance with embodiments of the present disclosure, the processor 906 is arranged to process the digital first output ‘U1’ and second output ‘U3’ sensed outputs conveying the grid-side voltage to compensate for the distortion introduced by the surge resistor R36 502.

The functionality of the processor 906 described herein may be implemented in code (e.g. instructions) stored on a memory (e.g. memory 910) comprising one or more storage media, and arranged for execution on a processor comprising one or more processing units. The storage media may be integrated into and/or separate from the processor 906. The code is configured so as when fetched from the memory and executed on the processor to perform operations in line with embodiments discussed herein. The instructions, when executed by the processor, may cause the processor to perform any of the methods described herein. These instructions may be provided on a non-transitory computer-readable medium. These instructions may be provided on a carrier such as a disk, CD- or DVD-ROM, programmed memory such as read-only memory (Firmware), or on a data carrier such as an optical or electrical signal carrier. Alternatively, it is not excluded that some or all of the functionality of the processor 906 is implemented in dedicated hardware circuitry (e.g. ASIC(s), simple circuits, gates, logic, and/or configurable hardware circuitry like an FPGA).

In some embodiments of the present disclosure, the processor 906 is arranged to compensate for the distortion introduced by the surge resistor R36 502 using knowledge of a current at an input terminal of the power supply 560. In other embodiments, the processor 906 is arranged to compensate for the distortion introduced by the surge resistor R36 502 without knowledge of a current at an input terminal of the power supply 560. The input terminal of the power supply 560 referred to above may correspond to input terminal 590 or input terminal 595 shown in FIG. 5.

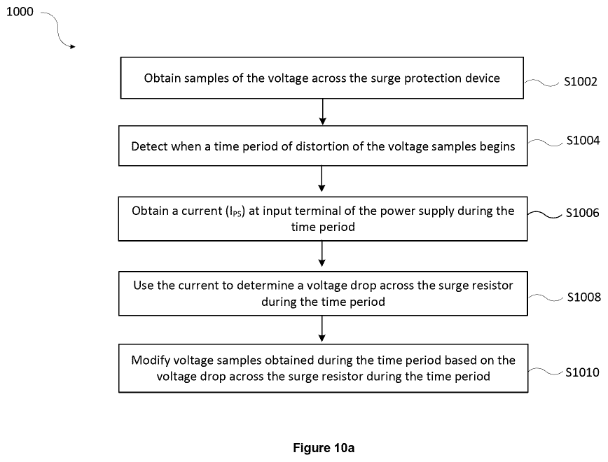

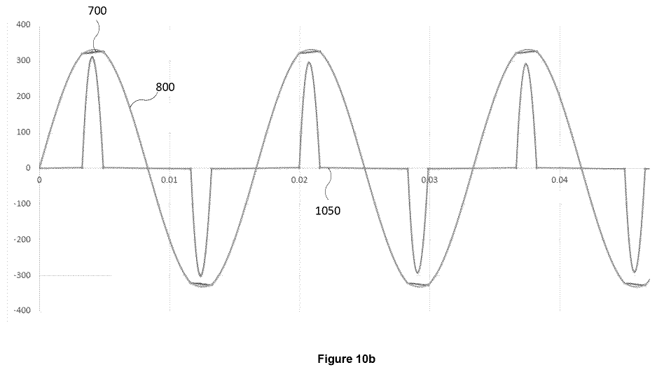

We first describe embodiments in which the processor 906 is arranged to compensate for the distortion introduced by the surge resistor R36 502 using knowledge of the current at the input terminal of the power supply 560, with reference to the flowchart shown in FIG. 10a.

FIG. 10a is a flowchart illustrating a method 1000 which may be performed by the processor 906 of the analog front end circuitry 970.

As shown in FIG. 10a, at step S1002 the processor 906 obtain samples of the voltage across the surge protection device 555 (the measured grid-side voltage waveform) based on receiving the digital first output ‘U1’ and second output ‘U3. The measured grid-side voltage waveform may be measured by the grid voltage sensing circuit 580G of FIG. 5.

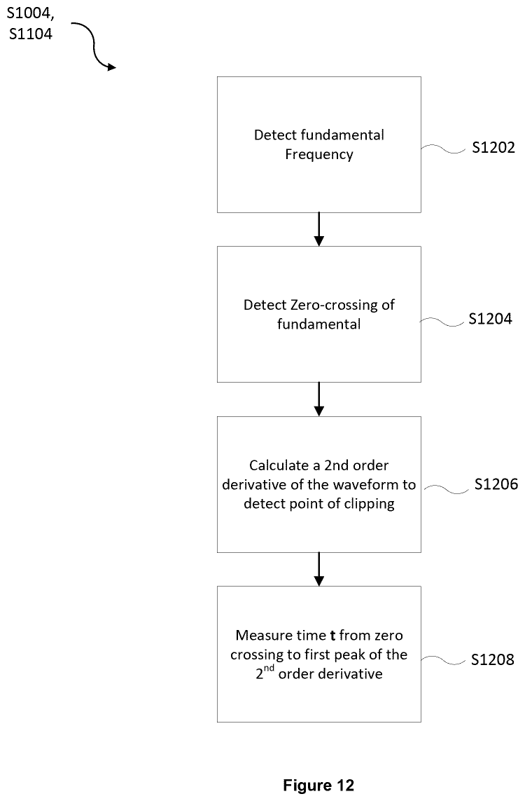

At step S1004, the processor 906 detects a time t when a time period of distortion Tp of the grid-side voltage waveform begins (the distortion illustrated in FIG. 7). Various techniques may be employed by the processor 906 to perform step S1004. One example technique is described in more detail below with reference to FIG. 12.

At step S1006, the processor 906 obtains the current (I_{PS}) at an input terminal of the power supply 560 during the time period of distortion Tp of the grid-side voltage.

In some implementations, the circuit 500 comprises a current sensing device operable to measure the current (I_{PS}) at the input terminal of the power supply 560. In these embodiments, the processor 906 obtains the current (I_{PS}) based on receiving a measurement signal output by the current sensing device. The current sensing device may be a resistor, Hall-Effect current sensor, or a magnetoresistive sensor.

The input terminal of the power supply 560 may correspond to input terminal 590 shown in FIG. 5. To ensure that all the supply current at the input terminal 590 of the power supply 560 is measured, the current sensing device is preferably located between the first node 505a and the input terminal 590 of the power supply 560 (e.g. the current sensing device may be located at node TP2 or located between nodes TP2 and TP4 of the circuit 500). In some implementations, the current sensing device may be placed in series with the differential choke L24. The differential choke L24 may be included in the circuit 500 to prevent conducted emissions produced from the power supply 560 from flowing back to the grid. In other implementations the current sensing device may be placed in series with, or replace, one or both of the resistors R684 and R685. In yet further implementations, the current sensing device may correspond to the combination of differential mode inductor L24 in parallel with the resistors R684 and R685.

The input terminal of the power supply 560 may correspond to input terminal 595 shown in FIG. 5. In particular, the current sensing device may be located between the second node 505c and the input terminal 595 of the power supply 560 (e.g. the current sensing device may be located at node TP5).

FIG. 10b illustrates the current (I_{PS}) 1050 at the input terminal of the power supply 560 which may be measured by the current sensing device referred to above.

In other implementations, the processor 906 obtains the current (I_{PS}) based on pre-stored characterisation data stored in memory (e.g. memory 910). In particular, the memory may store one or more predefined current profiles comprising data of how the current (I_{PS}) is expected to change over time in relation to the grid-side voltage. Each of the one or more predefined current profiles may be associated with an operating mode of the electricity meter (e.g. a radio transmit operation mode, a service disconnect operation mode, transmitters in receive mode, or a firmware update mode), and the processor 906 may be configured to retrieve a predefined current profile which corresponds to the operating mode of the electricity meter. In these implementations, it will be appreciated that the current (I_{PS}) is not measured. Instead, the processor 906 is configured to determine the current (I_{PS}) based on the sensed grid-side voltage and a predefined current profile. FIG. 10b illustrates the current (I_{PS}) 1050 at the input terminal of the power supply 560 which may be obtained from a predefined current profile as described above. In these implementations, the processor 906 may perform step S1006 prior to, during, or after expiry of the time period of distortion Tp.

At step S1008, the processor 906 uses (i) the current (I_{PS}) at the input terminal of the power supply 560 during a time period of distortion Tp and (ii) the resistance value of the surge resistor R36 502, to determine a voltage drop across the surge resistor R36 502 (e.g. using the equation V=IR) during the time period of distortion Tp. It will be appreciated that the voltage drop across the surge resistor R36 502 will vary during the time period of distortion Tp.

At step S1010, the processor 906 is configured to modify samples of the measured voltage across the surge protection device 555 obtained during the time period of distortion Tp based on the voltage drop that occurs across the surge protection device during the time period of distortion Tp. That is, for each sample of the measured voltage across the surge protection device 555 obtained during the time period of distortion Tp, the processor 906 is configured to compensate for the distortion by adding the voltage drop occurring at the time the sample was obtained to the measured voltage to accurately reflect the voltage occurring on the grid.

Step S1008 may be performed dynamically during the time period of distortion Tp. Alternatively, step S1008 may be performed after expiry of the time period of distortion Tp. Step S1010 may be performed dynamically during the time period of distortion Tp. Alternatively, step S1010 may be performed after expiry of the time period of distortion Tp.

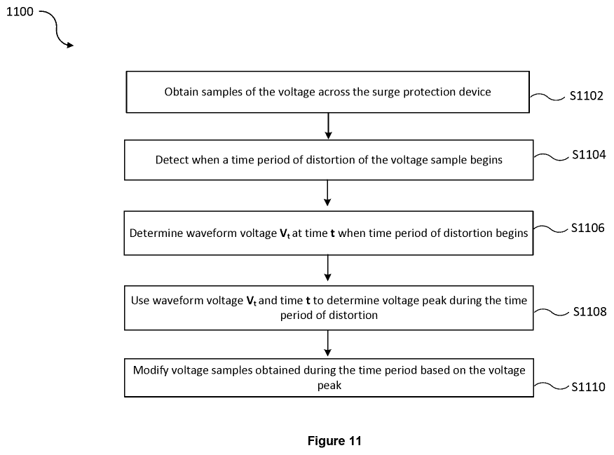

We now describe embodiments in which the processor 906 is arranged to compensate for the distortion introduced by the surge resistor R36 502 without knowledge of the current at the input terminal of the power supply 560, with reference to the flowchart shown in FIG. 11.

FIG. 11 is a flowchart illustrating a method 1100 which may be performed by the processor 906 of the analog front end circuitry 970.

As shown in FIG. 11, at step S1102 the processor 906 obtain samples of the voltage across the surge protection device 555 (the measured grid-side voltage waveform) based on receiving the digital first output ‘U1’ and second output ‘U3. The measured grid-side voltage waveform may be measured by the grid voltage sensing circuit 580G of FIG. 5.

At step S1104, the processor 906 detects a time t when a time period of distortion Tp of the grid-side voltage waveform begins (the distortion illustrated in FIG. 7). Various techniques may be employed by the processor 906 to perform step S1004. One example technique is described in more detail below with reference to FIG. 12.

At step S1106, the processor 906 is configured to determine a voltage Vₜ across the surge protection device 555 at the time t when the time period of distortion Tp of the grid-side voltage waveform begins.

At step S1108, the processor 906 is configured to use the voltage Vₜ and time t to determine a voltage peak Vₚₖ (which may be a positive or negative voltage peak) during the time period of distortion Tp. This voltage peak Vₚₖ is what has been clipped in the measured grid-side voltage samples during the time period of distortion Tp due to the distortion introduced by the resistor R36 502. In particular, the processor 906 may apply the values of the voltage Vₜ and time t to the formula below to determine a voltage peak Vₚₖ:

$${V}_{pk} = {V}_{t} / arcsine ( 2 π f * t )$$

whereby f is the fundamental frequency of the measured grid-side voltage. As explained below, the fundamental frequency f may be detected during step S1104 as part of the process to detect the time t when the time period of distortion Tp begins. Alternatively, the processor 906 may be configured to detect the fundamental frequency f as a separate step to step S1104.

At step S1110, the processor 906 is configured to modify samples of the measured voltage across the surge protection device 555 obtained during the time period of distortion Tp based on the voltage peak Vₚₖ to compensate for the distortion introduced by the surge resistor R36 502.

For example, the processor 906 may employ curve fitting techniques using the (i) samples of the measured voltage across the surge protection device 555 obtained prior to the time period of distortion Tp; (ii) the voltage peak Vₚₖ; and (iii) samples of the measured voltage across the surge protection device 555 obtained after the time period of distortion Tp; to determine a respective voltage that needs to be added to samples of the measured voltage during the time period of distortion Tp to accurately reflect the voltage occurring on the grid.

For each sample of the measured voltage across the surge protection device 555 obtained during the time period of distortion Tp, the processor 906 may be configured to compensate for the distortion by adding the voltage (determined for that sample using the curve fitting techniques) to the measured voltage to accurately reflect the voltage occurring on the grid.

FIG. 12 is a flowchart illustrating a method which may be performed by the processor 906 of the analog front end circuitry 970 at step S1004 and/or S1104 to detect the time t when a time period of distortion Tp of the grid-side voltage waveform begins.

At step S1202, the processor 906 is configured to process the samples of the voltage across the surge protection device 555 (the measured grid-side voltage waveform) to detect a fundamental frequency f.

At step S1204, the processor 906 is configured to process the samples of the voltage across the surge protection device 555 (the measured grid-side voltage waveform) to detect a zero crossing of the fundamental frequency (e.g. a point where the sign of the measured grid-side voltage changes, represented by a crossing of the x-axis (zero value) in the measured grid-side voltage waveform).

At step S1206, the processor 906 is configured to calculate a second order derivative of the measured grid-side voltage waveform to generate a second order derivative curve, and detect a point of clipping in the measured grid-side voltage waveform when a first peak of the second order derivative curve occurs (after the zero crossing).

At step S1208, the processor 906 is configured to measure the time t from the zero crossing of the fundamental frequency to the first peak of the second order derivative curve in order to determine the time t when the time period of distortion Tp of the grid-side voltage waveform begins.

It will be appreciated that other methods may be employed to detect when the time period of distortion Tp of the grid-side voltage waveform begins.

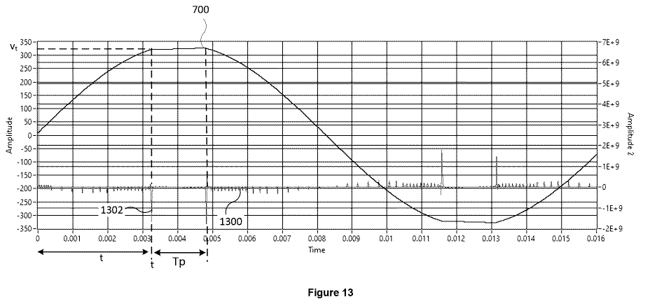

FIG. 13 illustrates the distorted grid-side voltage waveform 700 that may be measured by the grid voltage sensing circuit 580G of FIG. 5. As shown, the distorted grid-side voltage waveform 700 experiences a clipping effect during a time period Tp of distortion due to the power being drawn by the power supply 560. FIG. 13 also illustrates a second order derivative curve 1300 that may be computed by the processor 906. FIG. 13 illustrates a first peak 1302 of the second order derivative curve, the time t from the zero crossing of the fundamental frequency to the first peak 1302 of the second order derivative curve, and the time period Tp of distortion. Although the disclosure has been described in terms of particular embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

### LIST OF REFERENCE NUMERALS

| | |
|---|---|
| 100 | electricity meter |
| 105 | load |
| 110 | power-supply line |
| 115 | transformer |
| 120a | first input terminal |
| 120c | second input terminal |
| 130 | measurement circuitry |
| 135a | first node |
| 135c | second node |
| 140a | first output terminal |
| 140c | second output terminal |
| 145a | third node |
| 145c | fourth node |
| 150a | first current transformer |
| 150c | second current transformer |
| 200 | electricity meter |
| 205 | load |
| 215 | grid |
| 220a | first input terminal |
| 220c | second input terminal |
| 230 | measurement circuitry |
| 240a | first output terminal |
| 240c | second output terminal |
| 260 | power supply |
| 265 | actuator |
| 270 | analog front end |
| 275 | digital circuitry |
| 280G | grid voltage sensing circuit |
| 280L | load voltage sensing circuit |
| 290a | first current sensing circuit |
| 290c | second current sensing circuit |
| 295 | service disconnect switch |
| 300 | circuit |
| 320a | first input terminal |
| 320c | second input terminal |
| 325a | first output |
| 325c | second output |
| 345a | first resistor string |
| 345c | second resistor string |
| 400 | electricity meter |
| 405 | load |
| 415 | grid |
| 420a | first input terminal |
| 420c | second input terminal |
| 430 | measurement circuitry |
| 440a | first output terminal |
| 440c | second output terminal |
| 455 | surge protection device |
| 460 | power supply |
| 465 | actuator |
| 470 | analog front end |
| 475 | digital circuitry |
| 480G | grid voltage sensing circuit |
| 480L | load voltage sensing circuit |
| 490a | first current sensing circuit |
| 490c | second current sensing circuit |
| 495 | service disconnect switch |
| 500 | circuit |
| 502 | surge protection element |
| 505a | first node |
| 505c | second node |
| 510a | first voltage divider |
| 510c | second voltage divider |
| 555 | surge protection device |
| 560 | power supply590 input |
| | terminal |
| 595 | input terminal |
| 660 | power supply |
| 602 | surge protection element |
| 700 | distorted grid-side voltage |
| | waveform |
| 800 | grid-side voltage waveform |
| 902 | anti-aliasing filter |
| 904 | analogue-to-digital converter |
| 906 | processor |
| 910 | memory |
| 912 | anti-aliasing filter |
| 914 | analogue-to-digital converter |
| 970 | analog front end circuitry |
| 1050 | current |
| 1300 | second order derivative curve |
| 1302 | first peak |

1. An electricity meter comprising:
a power supply for supplying power to measurement circuitry; and
a surge protection device for protecting an input to the power supply;
wherein the measurement circuitry is configured to measure a voltage across the surge protection device.

2. The electricity meter of claim 1, wherein the surge protection device comprises at least one of:
a Metal-Oxide Varistor (MOV);
a Gas Discharge Tube (GDT);
a Transient Voltage Suppressor (TVS) diode; and/or
a Polymeric Positive Temperature Coefficient Device (PPTC).

3. The electricity meter of claim 1, wherein the input comprises a first voltage input (VA_LINE) and a second voltage input (VC_LINE), and wherein the surge protection device is connected to a first node coupled to the first voltage input and a second node coupled to the second voltage input.

4. The electricity meter of claim 3 wherein, in use, the first voltage input (VA_LINE) has a first phase and the second voltage input (VC_LINE) has a second phase out of phase with the first phase.

5. The electricity meter of claim 3, comprising a first voltage divider coupled to the first node and a second voltage divider coupled to the second node, wherein the measurement circuitry is configured to measure voltages at each of the first and second dividers to determine the voltage across the surge protection device.

6. The electricity meter of claim 5, wherein:
the first and second voltage dividers are configured to tolerate a clamping voltage of the surge protection device; and
at least one of the first and second voltage dividers comprises: a resistive divider; a capacitive divider; or an inductive divider.

7. The electricity meter of claim 3, comprising a first linear transformer coupled to the first node and a second linear transformer coupled to the second node, wherein the measurement circuitry is configured to measure voltages at each of the first and second linear transformers to determine the voltage across the surge protection device.

8. The electricity meter of claim 3, further comprising a surge protection element between the first voltage input (VA_LINE) and the first node.

9. The electricity meter of claim 8, wherein the surge protection element is a resistor.

10. The electricity meter of claim 8, wherein the measurement circuitry comprises a processor configured to:
obtain samples of the measured voltage across the surge protection device;
detect when a time period of distortion of the measured voltage across the surge protection device begins;
obtain current values at an input terminal of the power supply during the time period;
use the current values to determine a voltage drop across the surge protection device during the time period; and
modify samples of the measured voltage across the surge protection device obtained during the time period based on the voltage drop across the surge protection device during the time period.

11. The electricity meter of claim 10, further comprising a current sensing device arranged to output said current values.

12. The electricity meter of claim 11, wherein the current sensing device is connected between the first node and the input terminal.

13. The electricity meter of claim 10, wherein the current values are pre-stored in a memory accessible by the processor, and the processor is configured to obtain the current values by retrieving the current values from the memory.

14. The electricity meter of claim 13, wherein the processor is configured to retrieve the current values from the memory based on an operating mode of the electricity meter.

15. The electricity meter of claim 8, wherein the measurement circuitry comprises a processor configured to:
obtain samples of the measured voltage across the surge protection device;
detect when a time period of distortion of the measured voltage across the surge protection device begins;
determine a voltage peak during the time period of distortion using: (i) the measured voltage across the surge protection device when the time period of distortion begins, and (ii) a time between a zero-crossing of the measured voltage across the surge protection device, and when the time period of distortion of the measured voltage across the surge protection device begins; and
modify samples of the measured voltage across the surge protection device obtained during the time period based on the voltage peak.

16. The electricity meter of claim 1, wherein the power supply comprises at least one rectifier and/or regulator circuit configured to supply power to the measurement circuitry.

17. The electricity meter of claim 1, comprising an actuatable switch for selectively coupling a grid-side input of the electricity meter to a load side output of the electricity meter.

18. The electricity meter of claim 17, wherein:
the measurement circuitry is configured to measure a load-side voltage at the load-side output of the actuatable switch;
the measurement circuitry is configured to measure a load-side current at the load-side output of the actuatable switch; and
the voltage across the surge protection device corresponds to a voltage at a grid-side input of the actuatable switch.

19. The electricity meter of claim 18, comprising control circuitry and communication circuitry, wherein the control circuitry is configured to selectively actuate the actuatable switch based, at least in part, on:
the voltage at a grid-side input as measured by the measurement circuitry;
the load-side voltage as measured by the measurement circuitry; and/or
data received by the communication circuitry.

20. A method of operating an electricity meter, the method comprising configuring measurement circuitry to measure a voltage across a surge protection device, wherein the surge protection device is configured to protect an input to a power supply configured to supply power to the measurement circuitry.

21-23. (canceled)
